(19) United States
(12) Patent Application Publication
(10) Pub. No.: US 2003/0183718 A1
(43) Pub. Date: Oct. 2, 2003

(54) Reels with directly secured flanges

(76) Inventors: Gerald H. Davis, Fountain City, IN (US); Gary L. Cox, Richmond, IN (US); Chad L. Eversole, Richmond, IN (US)

Correspondence Address: Harold C. Moore, Maginot, Moore & Bowman, Bank One Center/Tower, 111 Monument Circle, Suite 3000, Indianapolis, IN, 46204-5115, US

(21) Appl. No.: 10/319,795

(22) Filed: Dec. 13, 2002

Related U.S. Application Data
(63) Continuation-in-part of application No. 10/108,790, filed on Mar. 29, 2002.

(51) Int. Cl. H01L 21/66; G01R 31/26; B65H 16/02; B65H 18/02; B65H 49/04; B65H 49/20; B65H 75/00; B65H 49/38; B65H 75/14; B65H 75/18

(52) U.S. Cl. 242/600; 242/590; 242/570; 242/607; 242/608; 242/608.2; 242/608.4; 242/609; 242/609.1; 242/609.2

(57) ABSTRACT

An apparatus for supporting wound flexible media that includes a first flange, a second flange and a fastener. The second flange may be constructed as an integral, unitary structure. A core around which flexible media is wound is typically disposed between the first flange and the second flange. The first fastener has a first end engaging the first flange and a threaded end that is rotatably secured directly to said second flange.

This application is a continuation-in-part filed under 35 U.S.C. §120 and thereby claims the benefit of U.S. patent application Ser. No. 10/108,790, which is incorporated herein by reference.

### FIELD OF THE INVENTION

The present invention relates generally to reels for supporting or storing flexible media, and more particularly, reels having a central core secured between two flanges.

### BACKGROUND OF THE INVENTION

Reels for storing flexible media, such as wire, hose, chain link, or rope, typically comprise a core interposed between two flanges. In general, the flexible media is rotatably wrapped around the core. The flanges provide axial retention of the flexible media on the core, and may include structures that facilitate rotation of the reel. For example, the flanges may include drive holes that receive a drive mechanism that rotates the reel.

Ideally, a reel combines structural strength with convenience and economy of manufacture. Reels are commonly produced by assembling individually manufactured flanges and cores. In one common reel design, bolt and nut type fasteners join the components. In this design, bolts extend through one flange, through the interior of the core, and then through the second flange. The head of the bolt extends outwardly away from the flange surface and the opposite end of the bolt extends outwardly from the other flange surface. The nut is then affixed to the exposed end of the bolt, thereby trapping the two flanges and the core between the head of the bolt and the nut.

While this arrangement is simple and effective, it has some limitations. Assembly of the nut and bolt arrangement requires several steps as well as several components, adding to the complexity of the manufacturing process. In particular, multiple bolts and their corresponding nuts must be inventoried and assembled.

In addition, threading each bolt through the flanges presents alignment issues. Because the bolt is threaded through the inside of the core, the assembler cannot readily use visual feedback to align the bolt with the hole in the second flange. Moreover, manipulation and application of the nuts adds to the manufacturing complexity.

Such challenges are not necessarily limited to a one-time manufacturing process. Indeed, it is often desirable to disassemble a reel upon consuming the media to facilitate return and re-use of the reel. Specifically, used reels are often stored and/or shipped for re-use. Disassembly for storage or shipment is advantageous because the disassembled components of the reel occupy a smaller volume than an assembled reel. Accordingly, the problems associated with the assembling the nut and bolt reel design are not necessarily limited to initial manufacture of the reel, but resurface throughout the life of the reel.

A second method for fastening the components is to design the reel components to “snap” together. While this method does not require bolts or nuts, the method requires patterns that will fit together and stay together. “Snap” together patterns often complicate the manufacture of the individual components. Additionally, patterns that are less likely to come apart can be more difficult to disassemble. Finally, it is difficult to obtain the same load bearing strength in a snap together reel, as that which is possible with a bolted reel.

A need therefore exists for a lightweight reel that has structurally strong means by which the flanges are attached to the core. A further need exists for a reel that is assembled requiring a reduced number of parts and is easily disassembled and reassembled.

### SUMMARY OF THE INVENTION

The present invention fulfills the above needs, as well as others, by providing a reel comprising a core, two flanges, and a threaded fastener that is secured directly to the flange. Because the threaded fastener is secured directly to the flange, the reel according to the present invention does not require nuts. In another aspect of the present invention, a reel includes fastener funnels assist in guiding the fastener to threading openings in the flange, which is advantageous because the reel core conceals the fastener as it is being threaded through the opposing flange.

A first embodiment of the invention is an apparatus for supporting wound flexible media that includes a first flange, a second flange and a threaded fastener. The second flange is constructed as an integral, unitary structure. The first fastener has a first end engaging the first flange and a threaded end that is rotatably secured directly to said second flange.

A second embodiment of the invention is an apparatus for supporting wound flexible media that also includes a first flange, second flange and a fastener, and further includes a core. The first flange includes at least a first fastener opening, and the second flange includes at least a second fastener opening. The core is disposed between the first flange and the second flange. The fastener has a first end and a second end, and extends through the first opening the core and at least a part of the second opening. The second flange further includes one or more guiding structures configured to urge the second end of the fastener toward the second opening responsive to axial components of force moving the second end towards the second flange.

It will be appreciated that the direct fastening design need not employ guiding structures to obtain at least some of the advantages of the present invention. In other words, the use of direct flange fastener eliminates the complexity added by the use of nuts, and results in fewer parts to inventory and manipulate.

Similarly, a traditional bolt and nut reel design can benefit from the guiding structures. Accordingly, the direct fastening aspect and the guiding structure aspect can stand alone as separate, valuable features.

The above described features and advantages, as well as others, will become more readily apparent to those of ordinary skill in the art by reference to the following detailed description and accompanying drawings.

### BRIEF DESCRIPTION OF THE DRAWINGS

FIG. 1 shows a perspective view of an exemplary embodiment of a reel according to the present invention;

FIG. 2 shows a cross sectional view of the exemplary reel of FIG. 1;

FIG. 3 shows a perspective view of the outer side of a flange of the reel of FIG. 1;

FIG. 4 illustrates a perspective view of the inner side of the flange of FIG. 3;

FIG. 5 shows a cutaway perspective fragmentary view of the flange of FIG. 3;

FIG. 6 shows a cutaway perspective view of the reel of FIG. 1;

FIG. 7 shows a fragmentary plan view of a flange incorporating an alternative guiding structure;

FIG. 8 shows a fragmentary plan view of a flange incorporating another alternative guiding structure;

FIG. 9 shows a perspective view of an inner side of a second embodiment of a flange according to the present invention; and

FIG. 10 shows a top plan view of an outer side of the flange of FIG. 9.

### DETAILED DESCRIPTION

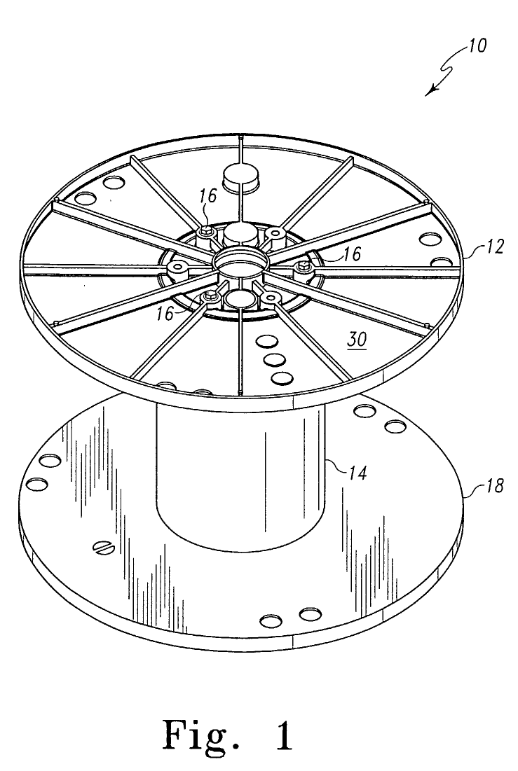

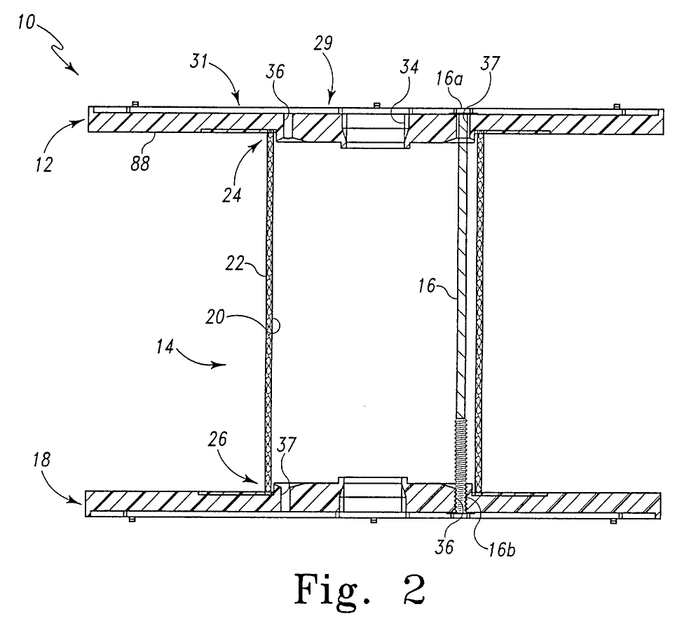

A first embodiment of an apparatus for supporting wound flexible media according to the invention is a reel 10 shown in FIG. 1. FIGS. 2-6 also show all or part of the reel 10 from other view points. Reference will be made generally to FIGS. 1-6 in the description of the reel 10 set forth herebelow. The reel 10 shown in those drawing figures illustrates one exemplary embodiment of the present invention. The individual inventive elements of the reel of the present invention, or portions thereof, may readily be incorporated into other reel designs, alone or in combination.

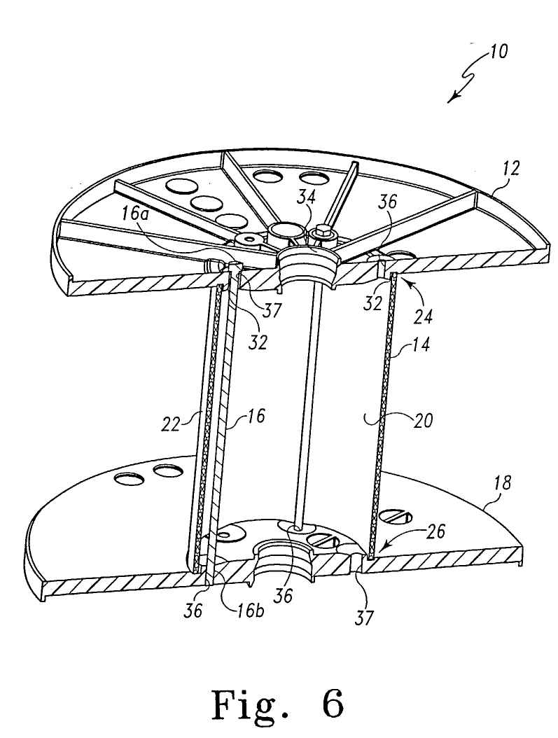

The reel 10 comprises a core 14, a first flange 12, a second flange 18, and fasteners 16. The fasteners 16 extend from the first flange 12 to the second flange 18. In accordance with one embodiment of the present invention, the fasteners are directly secured to the second flange 18. (See e.g. FIGS. 2 and 6). In this manner, the fasteners 16 secure the first flange 12 to the second flange 18 without the need for nuts, cotter pins, or other separate end retention mechanism. In a preferred embodiment, the fasteners 16 are threaded fasteners, such as screws or bolts.

The fasteners 16 connect the first flange 12 and the second flange 18 with the core 14 disposed between the first flange 12 and the second flange 18. The reel shown is approximately fourteen inches in diameter. However, other reels of other sizes may readily incorporate the features of the present invention.

The core 14 is a supporting structure, typically having an open interior, that is configured to receive wound media, such as cable, wire, rope, hose or other material that may be flexibly wound. In the exemplary embodiment described herein, the core 14 is a hollow cylindrical structure. In other embodiments, however, the core 14 may take other shapes, such as those having a polygonal or elliptical cross section. Nevertheless, the cylindrical structure is preferable for its strength qualities as well as its ability to provide an even, smooth surface for the media loaded onto the reel 10.

Referring again to the embodiment of FIGS. 2 and 6, the core 14 has a first end 24 and a second end 26 axially separated by the body of the core 14. The core 14 includes an inner surface 20 and an outer surface 22. In the preferred embodiment the core is preferably a hollow cylindrical structure constructed of materials such as wood, plastic, or paper.

The first flange 12 is formed as a unitary structure, preferably injection molded or cast. As such, the structural features of the first flange 12, which may or may not have relatively complex shapes, are readily constructed at relatively low cost, as compared to assembling a flange from multiple structure elements.

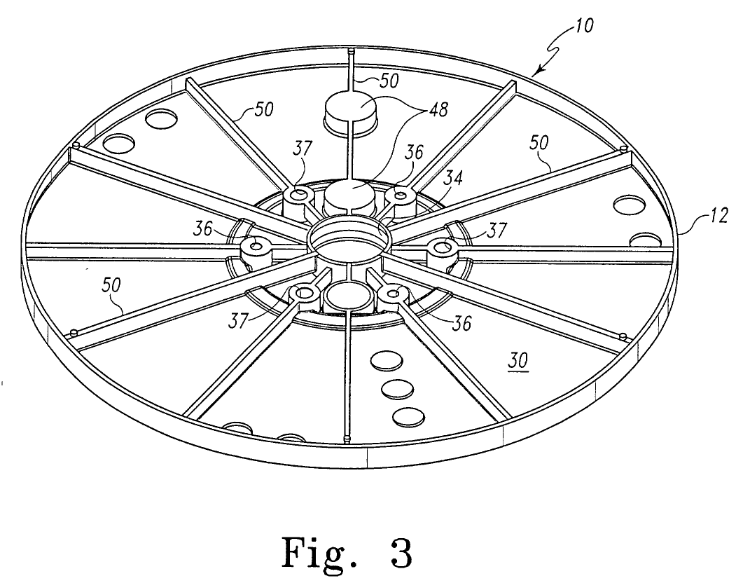

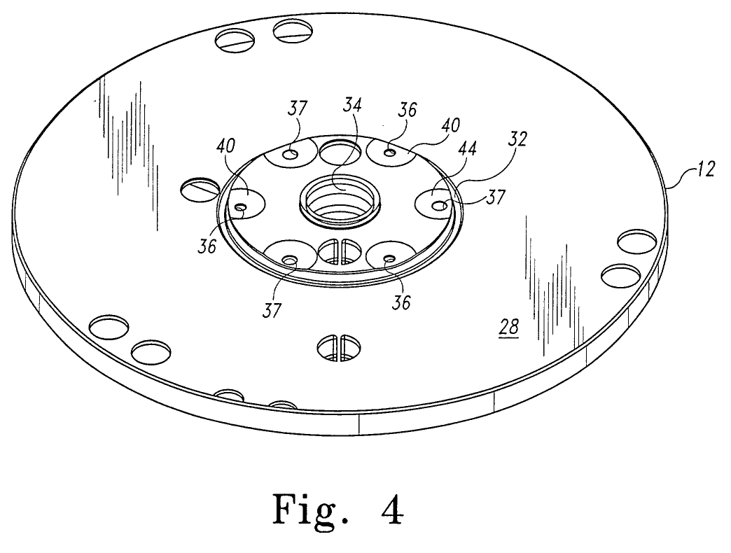

In any event, the first flange 12 is generally a disc-shaped body having central section 29 and a load bearing section 31. The central section 29 is radially inward of the load bearing section 31, with the core 14 generally defining the border between the central section 29 and the load bearing section 31. The central section 29 includes a bore 34 defined at its center. The first flange 12 further includes two axially facing sides, a media side or inner side 28 (FIG. 4) and an outer side 30 (FIG. 3). The first flange 12 is preferably constructed from plastic, for reasons discussed further below. However, the first flange 12 may alternatively be constructed of metal, wood or paper.

A core groove 32 is preferably defined in the surface of the media side 28 and has a shape that is configured to receive the first end 24 of the core 14 when the reel 10 is assembled. (See FIGS. 4 and 6). The core groove 32 is ideally of sufficient depth to reduce the potential for the core 14 from radially dislodging from the flange 12. In the exemplary embodiment described herein, the core groove 32 depth is on the order of 1/16 inch. While the core groove 32 helps secure the core 14 to the first flange 12, it is noted that other features which would be readily apparent to those of ordinary skill in the art may engage the first end 24 of the core 14 to help retain its position on the first flange 12.

In the exemplary embodiment described herein, the first flange 12 includes a number of gripping openings 36 and a number of boss openings 37 defined therein. The boss openings 37 and preferably also the gripping openings 36 extend from the inner side 28 to the outer side 30. The openings 36, 37 are arranged in alternating fashion in a circular pattern, spaced an equal distance apart. The openings 36, 37 are disposed on the central section 29 between the bore 34 and the core groove 32 and are preferably positioned proximate to the core groove 32. It is noted that in the embodiment described herein, the second flange 18 also includes similar gripping openings 36 and boss openings 37, as shown in FIG. 2.

In general, the boss openings 37 are configured to slidably receive the fastener 16 until a head 16a at the first end of the fastener 16 engages the material of the central section 29 immediately surrounding the boss opening 37. (See, e.g. FIGS. 2 and 6). By contrast, the gripping openings 36 are configured to engage the second end (e.g. threaded end 16b) of a fastener such as the fastener 16. Typically, the first flange 12 may only include fasteners 16 inserted through the boss openings 37, while the second flange 14, which has a structure identical to that of the first flange 12, receives the threaded end 16b of the fasteners 16. In other words, the gripping openings 36 of the first flange 12 may not be used, and the boss openings 37 of the second flange 14 may not be used. Nevertheless, each of the flanges 12 and 14 has both gripping openings 36 and boss openings 37 available to facilitate the use of a single flange design for both flanges of the reel 10.

The location of the openings 36, 37 (and thus the fasteners 16) close to the core 14 provides mechanical advantages and also reduces the possibility that the first flange 12 will deflect away from the core 14 to become dislodged from the core groove 32.

Because of their distinct functions, the gripping openings 36 and the boss openings 37 are of two different diameters. The gripping openings 36 have a diameter that is less than the diameter of the fastener 16 measured thread-to-thread, and optionally less than the diameter of the fastener 16 measured at the shaft between the threads at the threaded end 16b. As a result, insertion of the fastener 16 into the gripping openings 36 expands and/or bores out the gripping openings 36, resulting in an inward bias against the threads and shaft of the fastener 16 to secure the fastener 16 in place. To enhance the gripping action about the fastener 16, it is preferable that the first flange 12 be constructed of plastic (polycarbonate, polyvinyl, polypropylene, ABS, styrene, etc.). It has been observed that polypropylene is particularly well suited for use the embodiments of the reel according to the invention described herein.

The boss openings 37 have a larger diameter, preferably slightly larger than the diameter of the fastener shaft and threads, such that the fasteners 16 may be relatively easily inserted through the boss openings 37. When the fasteners 16 are fully inserted, the heads of the fasteners 16 are disposed on the outer side 30 proximate the boss openings 37. On the opposing flange 18, the gripping openings 36 receive the threaded ends of the fasteners 16 (from the media side 28 outward).

As mentioned above, the second flange 18 in the exemplary embodiment described herein has an identical structure. Therefore, fasteners 16 maybe fed through boss openings 37 of the first flange 12 and secured in the gripping openings 36 of the second flange 18 and/or the fasteners may be fed through the boss openings 37 of the second flange 18 and secured in the gripping openings 36 of the first flange 12.

One or more fasteners 16 may be generally used. However, the use of three fasteners 16 is preferable because three connection points provide a relatively resilient connection. For ease of construction, the fasteners 16 are all fed from the first flange 12 (through boss openings 37) through the core 14 to the gripping openings 36 of the second flange 18. (See, e.g., FIGS. 2 and 6).

As discussed above, the alternating pattern of openings 36, 37 allows for a single flange design to be employed as both the first flange 12 and the second flange 18. As a result, only a single flange need be manufactured and stocked. However, it will be appreciated that the first and second flanges 12, 18 need not be identical. For example, one flange may contain nothing but boss openings and the other flange may contain nothing but gripping openings.

Referring again to the exemplary flange design of FIGS. 3 and 4, if it is desired to use a nut and bolt in lieu of direct fastening to the flange, the fastener 16 may be fed through the boss openings 37 of both the first flange 12 and the second flange 18. The nut, not shown, may then be rotatably secured to the exposed threads on the outer side of the second flange 18.

Returning to the preferred direct bolting embodiment, to facilitate inserting the fastener threads into the gripping openings 36, guiding structures in the form of funnels 40 are defined in the inner side 28 of the first flange 12 around the gripping openings 36. The funnels 40 are preferably conical shaped and are concentrically located with respect to the gripping openings 36. In general, however, the guiding structures need not be conical, but should include an angled surface or features that urge the threaded end 16b of the fastener 16 in the direction toward the opening 36 responsive to axial movement force in the direction of the second flange 18. In other words, if the fastener 16 is advanced towards the inner side of the flange such that it is off center with respect to the opening 36, then it engages a portion of the guiding structure that tends to push or urge it toward the opening 36.

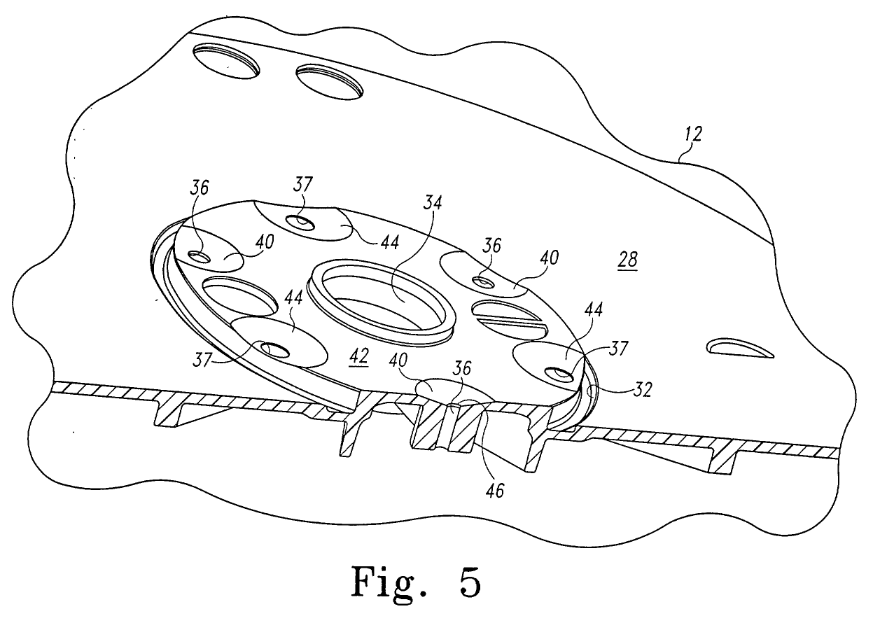

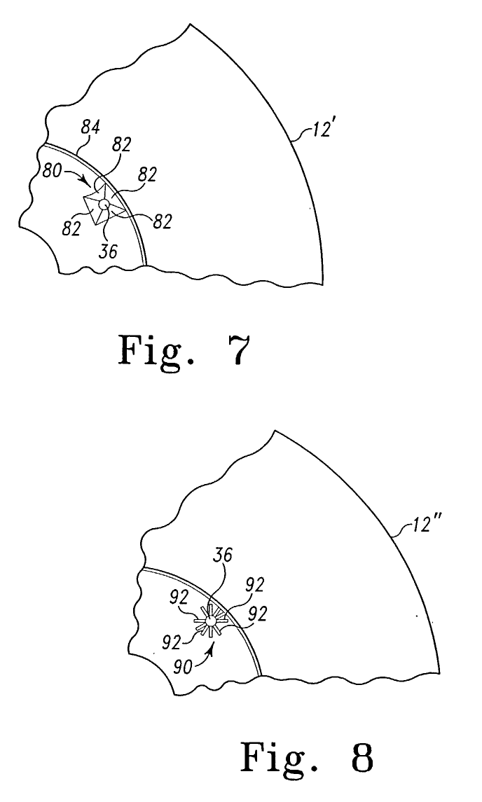

FIGS. 7 and 8 illustrate nonlimiting examples of non-conical guiding structures that may be used in accordance with other embodiments the present invention. FIG. 7 shows a fragmentary view of a flange 12′ that includes an alternative embodiment of the guiding structure 80. The guiding structure 80 comprises four relatively flat, inclined surfaces 82 forming an inverted pyramid with the inverted peak of of the pyramid being replaced by the gripping opening 36. As with the conical funnel 40 shown in FIG. 5, the guiding structure 80 is partially cut-off by the channel 84. As with all embodiments described herein, the inner surface of the core may itself assist in guiding the fastener when the core is disposed in the channel. It will be appreciated that the inverted pyramidal structure may be constructed using any number of inclined surfaces 82 other than four as shown.

FIG. 8 shows an example in which the guiding structure 90 is constructed of a plurality of inclined ribs 92. The ribs 92 extend upward from the flange 12″ and incline downward in the radial inward direction with respect to the gripping opening 36. As with all versions of the guiding structures, the inclined surface(s) that urge the fastener toward the gripping opening 36 need not have a constant slope, but may have a concave curved incline, or even an incline having multiple sloped and or curved segments.

All of the guiding structures aid in placement of the fastener 16 in the gripping hole 36. In particular, when assembling the reel 10, the core 14 as well as portions of the flanges 12 and 18 tend to obstruct a clear visual path to the opening 36 on the media side 28 of the flanges 12 and 18. Thus, alignment of the fastener 16 can be difficult. The guiding structures, however, allow for approximate alignment of the fastener 16 with the opening 36, because the guiding structures will urge a somewhat misaligned fastener 16 into alignment with the opening 36.

To provide a true advantage, the inclined surface or structure of the guiding structure on any one side of the gripping hole 36 (except where the core 14 is present) should be at least as wide as the diameter of the gripping hole 36. For ease of manufacturing, the bolt funnels 40 are preferably formed as recesses an otherwise relatively flat hub portion 42 of the flange 12. As such, during assembly, the assembler may miss the bolt funnel 40 completely, and slide the bolt end around on the flat hub portion 42 until the funnel 40 guides the bolt into alignment with the gripping hole 36. It is noted that because the openings 36, 37 are located close to the core 14, the core side of the bolt funnels 40 are interrupted or chorded where they intersect the core groove 32. As discussed above, it is advantageous for many reasons to locate the fasteners 16 radially close to the inside edge of the core 14. In that position, the inside surface 20 of the core 14 itself assists in guiding the fasteners 16 toward the gripper openings 36.

In addition, similar bolt funnels 44 are preferably defined in the media side 28 around the boss openings 37 to accommodate insertion of fasteners 16 in embodiments in which nuts are employed. In such embodiments, the threaded ends 16b of the fasteners 16 may be guided into the boss openings 37 in a similar manner as they are guided into the gripper openings 36 in the preferred embodiment. Accordingly, it may be appreciated that the advantages of using guiding structures may be obtained in reels that do not necessarily employ fasteners that directly secure to the flange.

As shown in FIG. 5 a threading aid 46 is defined in the intersection of the gripper hole 36 and the bolt funnel 40 on the media side 28 of the first flange 12. The threading aid 46 is frustoconical in shape, forming an annular chamfered edge around the gripping hole 36. The threading aid 46 facilitates the starting of the fastener 16 into the gripping hole 36. In general, the sloped edge of the threading aid 46 is sloped at a steeper angle than the bolt funnel 40.

Another aspect of the present invention are label platforms 48. Users of reels often use labels to identify, among other things, the type of media that is wound about the reel 10. Labels may take various sizes. Some labels are likely to be too large to fit between the ribs 50 of the outside surface 30 of the first flange 12. To accommodate such labels, two label platforms 48 extend axially away from the outside surface 30 of the first flange 12 to which the labels may be stapled. The surface of the label platforms 48 is preferably level with the upper surface of at least some of the ribs 50. A label, not shown, may be placed over the ribs 50 on the outside surface 30 of the first flange 12. The label is secured to the outside surface 30 of the first flange 12 via two staples, one staple secures the first end of a label to the first platform 48, and a second staple secures the second end of a label to the second platform 48. Alternatively, a media label may be secured to a single platform via a single staple.

In any event, the advantage of using a platform such as the platforms 48 is that the platform provides significant, relatively flat surface space, making it easier to align the stapling mechanism. To this end, the platforms should preferably be at least on the order of one inch wide in all directions. However, it will readily be appreciated that the advantages provided by direct fastening or the guiding structures may be obtained without incorporating platforms such as the platforms 48.

The reel 10 may suitably be constructed generally by first disposing the end 26 of the core 14 against the flange 18. In the exemplary embodiment describe herein, the end 26 is received by the core groove 32 of the flange 18. It is noted that the core groove 32 preferably includes structures, such as spikes, splines or other protrusions, not shown, that tend to deform or penetrate the core to assist in preventing relative rotation between the flange 18 and the core 14 during use. Such structures are described in further detail in U.S. Pat. No. 5,897,075, which is incorporated herein by reference.

In a similar manner, the flange 12 is disposed against the end 24 of the core 14. Again, the end 24 is inserted into the core groove 32 in the embodiment described herein. The flange 12 is preferably rotated until the boss openings 37 approximately align with the gripping openings of the flange 18.

Thereafter, a first fastener 16 is inserted into one of the boss openings 37 in the flange 12 and toward an opposing gripping opening 36 in the flange 18. As the second end 16b of the fastener 16 approaches the flange 18, if the second end 16b is misaligned with the gripping opening 36, then it engages the funnel 40 (or any of the alternative guiding structures). As further axial movement force is applied to the first fastener 16 (i.e. at the first end 16a), the funnel 40 (or any alternative guiding structure) translates the axial movement force to radial force toward the gripping opening 36.

When the second end 16b substantially engages the gripping opening 36, increased axial force combined with rotational movement is applied to the first end 16a. As a result, the second end 16b begins to bore out and/or expand the gripping opening 36 while advancing into the gripping opening 36. The axial and rotational movement is continued until the first end 16a engages the material of the flange 12 surrounding the boss opening 37 and the second end 16b is directly secured to the flange 18.

Second and third fasteners similar to the fastener 16 may be secured to the flange 18 in the same manner.

The above described embodiments are merely exemplary. Those of ordinary skill in the art may readily devise their own implementations that incorporate the principles of the present invention and fall within the spirit and scope thereof. For example, the claims below discuss a fastener, which could be, but need not be, the fastener 16. Other types of fasteners, including but not limited to rivets and the like, are contemplated. Moreover, while plastic is a material particularly well-suited for the gripping elements of the invention, and provides certain advantages in other respects, other materials may be used. In addition, it is contemplated that in some cases, the bolt or fastener may be self-tapping, thereby not requiring a pre-configured gripping hole 36. In such a case, insertion of the fastener itself creates the gripping hole 36. In such cases, it may be advantageous to include at least small starting feature such as the threading aid 46 of FIG. 5.

Moreover, some reel designs employ cores that are formed integrally with the flanges. For example, each flange may include a portion of the core. When the flanges are assembled to each other, the integrally-formed core portions combine to form a core disposed between the flanges. Such a design may readily employ the direct fastening features described above and/or the guiding structure features described above.

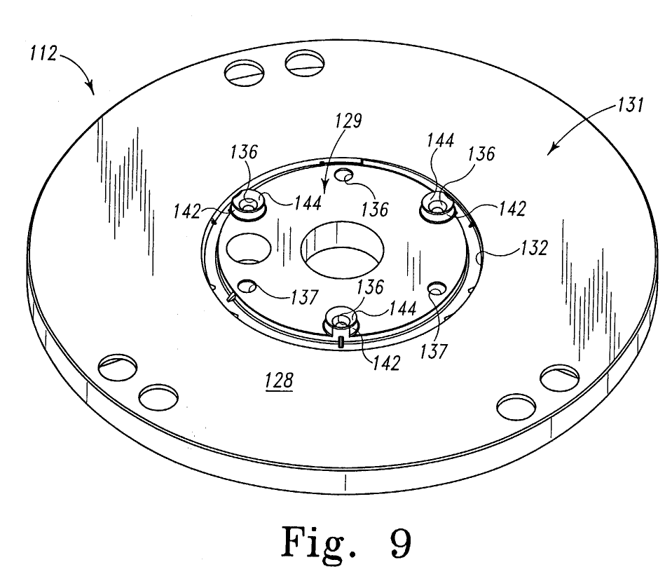

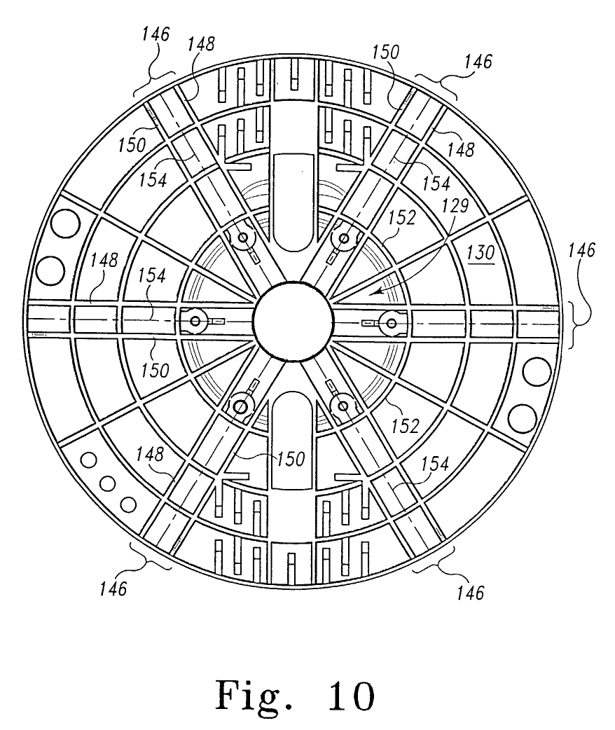

FIGS. 9 and 10 show another alternative embodiment of a flange 112 according to the present invention. The flange 112 may suitably be substituted for either or both of the flanges 12 and 14 of FIGS. 1-6.

The flange 112 may suitably be generally disc shaped. The flange 112 has central section 129 and a load bearing section 131. The central section 129 is radially inward of the load bearing section 131. The flange further includes a core groove 132 that generally defines the border between the central section 129 and the load bearing section 131. The central section 129 includes a bore 134 defined at its center. The flange 112 further includes two axially facing sides, a media side or inner side 128 (FIG. 9) and an outer side 130 (FIG. 10). The flange 112 is most advantageously constructed of plastic, but may be constructed from metal, wood or paper. The core groove 132 defined in the surface of the media side 128 has a shape that is configured to a first end of a core of the reel.

In the exemplary embodiment described herein, the flange 112 includes a number of gripping openings 136 and a number of boss openings 137 defined therein. The boss openings 137 and preferably also the gripping openings 136 extend from the inner side 128 to the outer side 130. The openings 136, 137 are arranged in alternating fashion in a circular pattern, spaced an equal distance apart. The openings 136, 137 are disposed on the central section 129 between the bore 134 and the core groove 132 and are preferably positioned proximate to the core groove 132.

In general, the boss openings 137 are configured function in a manner largely identical to the boss openings 37 of the embodiment of FIGS. 1-6. In other words, the boss openings 137 slidably receive a fastener such as the fastener 16 of FIGS. 2 and 6 until the fastener head engages the material of the central section 129 immediately surrounding the boss opening 137. (See, e.g. FIGS. 2 and 6). Also similar to the embodiments of FIGS. 2 and 6, the gripping openings 36 are configured to engage and directly secure the other end of the fastener.

Similar to the embodiment of FIGS. 1-6, the gripping openings 136 and the boss openings 137 are of two different diameters. The gripping openings 136 have a diameter that is less than the diameter of the fastener. As a result, insertion of the fastener into the gripping openings 136 expands and/or bores out the gripping openings 136, resulting in an inward bias against the threads and shaft of the fastener to secure the fastener in place. To enhance the gripping action about the fastener, it is preferable that the first flange 12 be constructed of plastic (polycarbonate, polyvinyl, etc.). The boss openings 137 have a larger diameter, preferably slightly larger than the diameter of the fastener, such that the fasteners may be relatively easily inserted through the boss openings 137.

To facilitate inserting the fastener threads into the gripping openings 136, guiding structures 140 are defined in the inner side 128 of the flange 112 around the gripping openings 136. The guiding structures 140 include an outer support surface 142 and an inner guiding surface 144. The outer support surface 142 that extends axially upward (i.e, inward) from the inner side 128 of the flange 112. In the exemplary embodiment described herein, the outer support surface 142 is preferably cylindrical. The inner guiding surface 144 is a conical funnel that guides the fastener toward the associated gripping opening 136.

The flange 112 of FIGS. 9 and 10 further includes an advantageous rib structure that provides advantages that are largely independent of the advantages provided by direct fastening and/or the use of guiding structures. The outer side 130 of the flange 112 includes a plurality of sets of parallel radial ribs 146. Each set of parallel radial ribs 146 includes a first rib 148 and a second rib 150 that are spaced apart and extend substantially parallel to each other from the outer rim 147 to proximate the bore 134. Alternatively, the ribs 148 and 150 may extend to at least the rim 152 defined by the core groove 132 of the inner side 128.

The ribs 148 and 150 do not extend in a perfectly radial direction. Instead, the ribs 148 and 150 extend in a slightly non-radial direction. In particular, each rib 148 and 150 preferably extends parallel to a radial line 154 that is equidistant from the ribs 148 and 150. The distance between the ribs 148 and 150 is preferably less than the diameter of the bore 134.

It has been found that the use of parallel ribs as opposed to strictly single radial ribs provides better reinforcement along the radial lines that incorporate the openings 136, 137 without interruption in the rib reinforcement by the openings 136, 137. Thus, the reinforcement strength is focussed on the potential load bearing portions of the flange 112, namely the openings 136 or 137, while avoiding weakening of the rib which can occur if the rib is interrupted by the openings 136 and 137.

It will be appreciated that the above embodiments are merely exemplary, and that those of ordinary skill in the art may readily devise their own implementations and adaptations that incorporate the principles of the present invention and fall within the spirit and scope thereof.

Moreover, many detailed features have been disclosed herein that provide additional advantages beyond those of the present invention, or indeed enhance the present invention. It will be appreciated that many of the advantages of the present invention may be obtained without such detailed features. Accordingly, the claims defined below are not intended to incorporate portions or details of the disclosed embodiments that are not expressly recited in the claims. The principles of the present invention have widespread applications, and may be incorporated into an infinite number of reel designs by those of ordinary skill in the art.

We claim:

1. An apparatus for supporting wound flexible media comprising:
a first flange and a second flange, the second flange constructed as an integral, unitary structure;
a first fastener, the first fastener having a first end engaging the first flange and a threaded end, the threaded end rotatably secured directly to said second flange.

2. The apparatus of claim 1 wherein the first fastener comprises a bolt.

3. The apparatus of claim 1 wherein the second flange is constructed of plastic.

4. The apparatus of claim 3 wherein the second flange comprises an integrally-molded plastic flange.

5. The apparatus of claim 1 further comprising a core interposed between the first flange and the second flange, said first fastener extending through said core.

6. The apparatus of claim 1 wherein the second end of the first fastener is disposed in an opening defined in the second flange, and the second flange further includes one or more guiding structures configured to urge the second end of the fastener toward the opening responsive to axial components of force moving the second end towards the second flange.

7. The apparatus of claim 1 wherein the one or more guiding structures include at least a portion of a conical funnel.

8. A flange for use in a reel for supporting wound flexible media, the flange comprising:
a first surface configured to axially retain wound flexible media on the reel,
a central structure integrally formed with the first surface and disposed radially inward of the first surface, the central structure including at least one fastener opening, each fastener opening configured to receive and securely engage a threaded end of a fastener.

9. The flange of claim 8 wherein the central structure includes at least one boss opening, the boss opening having a diameter exceeding a diameter of at least one fastener opening, the boss opening configured to slidingly receive the shaft of a fastener.

10. The flange of claim 8 wherein the fastener opening has a diameter less than a diameter the fastener.

11. The flange of claim 8 wherein the fastener opening defines a bore having a relatively cylindrical inner surface.

12. The flange of claim 8 further comprising one or more guiding structures configured to urge the threaded end of the fastener toward the fastener opening responsive to axial components of force moving the threaded end towards the second flange.

13. The flange of claim 12 wherein the one or more guiding structures include at least a portion of a conical funnel.

14. An apparatus for supporting wound flexible media comprising:
a first flange, the first flange constructed of a first unitary piece of molded plastic, the first flange including at least a first boss hole;
a second flange, the second flange constructed of a second unitary piece of molded plastic;
a core disposed between the first flange and the second flange; and
a first fastener, the first fastener having a first end engaging the first flange and a threaded end, the first end disposed proximate the first boss hole and the threaded end rotatably secured directly to said second flange.

15. The apparatus of claim 14 wherein the threaded end is disposed in an opening in the second flange, and the second flange further includes one or more guiding structures configured to urge the second end of the fastener toward a location of the opening responsive to axial components of force moving the second end towards the second flange.

16. The apparatus of claim 15 wherein the opening is created at least in part when the threaded end is secured to the second flange.

17. The apparatus of claim 15 wherein the one or more guiding structures include at least a portion of a conical funnel.

18. The apparatus of claim 14 wherein the first flange further includes second and third boss openings and further comprising:
a second fastener, the second fastener having a first end engaging the first flange and a threaded end, the first end disposed proximate the second boss hole and the second end rotatably secured directly to said second flange.
a third fastener, the first third having a first end engaging the first flange and a threaded end, the first end disposed proximate the third boss hole and the second end rotatably secured directly to said second flange.

19. A method of constructing an apparatus for supporting wound flexible media, the method comprising:
a) disposing a first end of a core against a first flange;
b) disposing a second flange against a second end of the core;
c) engaging the first flange with a first fastener, the first fastener including a first end and a threaded end, and securing the threaded end of the first fastener directly to the second flange.

20. The method of claim 19 wherein step c) further comprises advancing the threaded end of the first fastener toward the second flange and engaging guiding structures on the second flange, the guiding structures urging the threaded end of the first fastener to a securing location on the second flange.

21. The method of claim 19 wherein step b) further comprises disposing the second flange against the second end of the core, the second flange constructed of integrally molded plastic.

22. An apparatus for supporting wound flexible media comprising:
a first flange, the first flange including at least a first fastener opening;
a second flange, the second flange including at least a second fastener opening;
a core disposed between the first flange and the second flange; and
an elongate first fastener having a first end and a second end, the elongate first fastener extending through the first opening the core and at least a part of the second opening, and wherein;
the second flange further includes one or more guiding structures configured to urge the second end of the elongate first fastener toward the second opening responsive to axial components of force moving the second end towards the second flange.

23. The apparatus of claim 22 wherein the one or more guiding structures include at least a portion of a conical funnel.

24. The apparatus of claim 22 wherein the second opening in the second flange extends through to an external surface of the second flange, and at least a portion of the second end of elongate first fastener extends through the second opening.

25. The apparatus of claim 24 wherein the first fastener is a bolt, and further comprising a nut secured to the second end of the bolt.

26. A flange for use in an apparatus for supporting wound flexible media, the flange comprising:
a first surface configured to axially engage wound flexible media on the reel,
a central structure disposed radially inward of the first surface, the central structure including at least one fastener retaining feature, each fastener retaining feature including a first opening having a first diameter and a second opening aligned with the first opening and having a second diameter, the first diameter larger than the second diameter, and wherein the second opening is configured to receive and securely engage a threaded end of a fastener.

27. The flange of claim 26 wherein the first opening has a plurality of diameters that decrease as a function of axial depth from the first diameter.

28. The flange of claim 26 further including at least one fastener guiding feature, each fastener guiding feature including an opening having a diameter exceeding the second diameter.

29. The flange of claim 26 further comprising an annular core groove defined between the first surface and the central structure, the core groove configured to receive an end of a core of the reel.
